(19) United States
(12) Patent Application Publication
(10) Pub. No.: US 2012/0248517 A1
(43) Pub. Date: Oct. 4, 2012

(54) MAGNETIC MEMORY DEVICE

(75) Inventor: Hideaki HARAKAWA, Kanagawa-ken (JP)

(73) Assignee: KABUSHIKI KAISHA TOSHIBA, Tokyo (JP)

(21) Appl. No.: 13/241,060

(22) Filed: Sep. 22, 2011

(30) Foreign Application Priority Data
Mar. 28, 2011 (JP) 2011-069397

(51) Int. Cl. H01L 29/82

(52) U.S. Cl. 257/295; 257/421; 257/E29.323

(57) ABSTRACT

According to one embodiment, a magnetic memory device includes a substrate and a plurality of magneto-resistive effect devices provided on a substrate. Two of the plurality of magneto-resistive effect devices, that are nearest to each other when viewed from above, differ from each other in distance from the substrate.

### CROSS-REFERENCE TO RELATED APPLICATIONS

This application is based upon and claims the benefit of priority from the prior Japanese Patent Application No. 2011-069397, filed on Mar. 28, 2011; the entire contents of which are incorporated herein by reference.

### FIELD

Embodiments described herein relate generally to a magnetic memory device.

### BACKGROUND

The development of Magneto-resistive Random Access Memory (MRAM) as high-speed, no-write-limit, non-volatile memory has been in progress for some time. In MRAM, magneto-resistive effect devices are provided as memory devices, each having a reference layer of fixed magnetization direction, a memory layer of rotatable magnetization direction, and an insulating layer (barrier layer) inserted between the reference layer and the memory layer. Data can then be written by controlling the magnetization direction of the memory layer, and the written data can be read by using the fact that electrical resistance of magneto-resistive effect devices varies according to whether the magnetization direction of the memory layer and the magnetization direction of the reference layer are parallel or anti-parallel.

As a method for controlling the magnetization direction of the memory layer, a method has been proposed in which magnetic fields are formed by passing current along a word line and a bit line. However, with this method, a space is required to form the magnetic field around the word line and the bit line, and so it is difficult to narrow the arrangement interval for the word line and the bit line, and there is a limit on miniaturization. To solve this problem, spin-injection type MRAM in which the magnetization direction of the memory layer is controlled by injecting electrons with spin directions aligned in a fixed direction has been proposed. With this technique, an arrangement period of the word lines and the bit lines can be narrowed.

### BRIEF DESCRIPTION OF THE DRAWINGS

FIG. 1 is a perspective view illustrating a magnetic memory device according to an embodiment;

FIG. 2 is a plan view illustrating the magnetic memory device according to the embodiment;

FIG. 3A is a partial plan view illustrating the magnetic memory device according to the embodiment, FIG. 3B is a cross-sectional view taken along A-A′ in FIG. 3A, and FIG. 3C is a cross-sectional view taken along B-B′ in FIG. 3A;

FIGS. 4 to 9 are process views illustrating a method for manufacturing the magnetic memory device according to the embodiment; and

FIGS. 10A and 10B are views illustrating the effects of the embodiment.

### DETAILED DESCRIPTION

In general, according to one embodiment, a magnetic memory device includes a semiconductor substrate, a gate insulating film, a plurality of first and second word lines, a first bit line and a second bit line, a plurality of pairs of first source-drain regions, a plurality of pairs of second source-drain regions, spin-injection type first magneto-resistive effect devices, spin-injection type second magneto-resistive effect devices, first contacts, second contacts, first upper electrodes, and second upper electrodes. The gate insulating film is provided on the semiconductor substrate. The plurality of first and second word lines are provided on the gate insulating film, extend in a first direction, and are arranged alternately. The first and second bit lines are provided on the first and second word lines and extend in a second direction that is perpendicular to the first direction. The plurality of pairs of first source-drain regions are formed at intersections of the first word lines and the first bit line. Each pair of the first source-drain regions are formed in regions sandwiching a region directly below each of the first word lines in the semiconductor substrate when viewed from above. The plurality of pairs of second source-drain regions are formed at intersections of the second word lines and the second bit line. Each pair of the second source-drain regions are formed in regions sandwiching a region directly below each of the second word lines in the semiconductor substrate when viewed from above. A bottom end of each of the first magneto-resistive effect devices is connected to one region of each of the pairs of first source-drain regions. A bottom end of each of the second magneto-resistive effect devices is connected to one region of each of the pairs of second source-drain regions. A bottom end of each of the first contacts is connected to another region of each of the pairs of first source-drain regions. A bottom end of each of the second contacts is connected to another region of each of the pairs of second source-drain regions. The first upper electrodes are connected to top ends of the first magneto-resistive effect devices, top ends of the second contacts, and the second bit line. The second upper electrodes connected to top ends of the second magneto-resistive effect devices, top ends of the first contacts, and the first bit line. The second magneto-resistive effect devices are disposed above the first magneto-resistive effect devices.

In general, according to one embodiment, a magnetic memory device includes a substrate and a plurality of magneto-resistive effect devices provided on the substrate. Two of the plurality of magneto-resistive effect devices, that are nearest to each other when viewed from above, differ from each other in distance from the substrate.

Various embodiments will be described hereinafter with reference to the accompanying drawings.

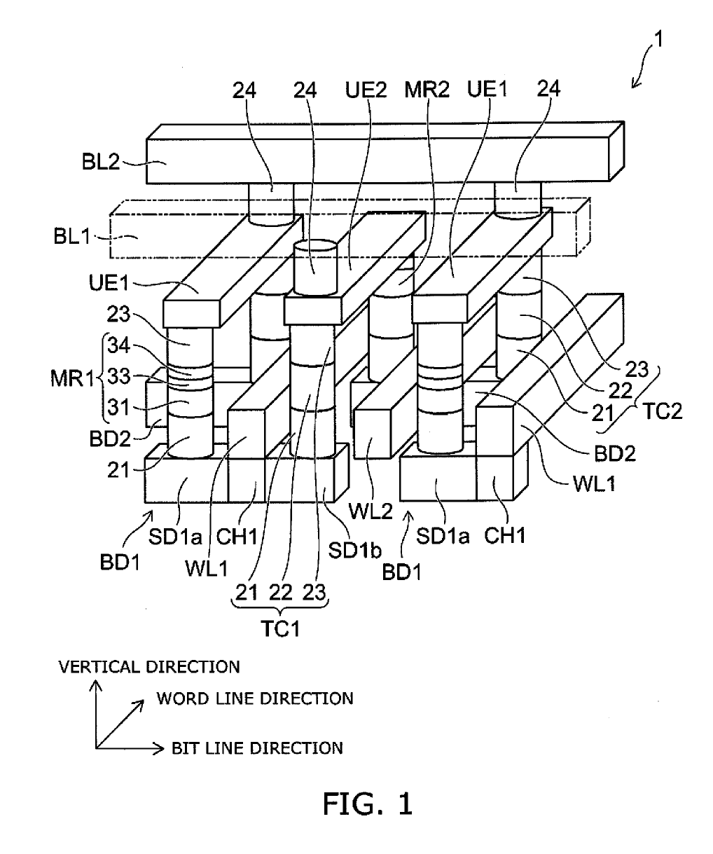

FIG. 1 is a perspective view illustrating a magnetic memory device according to the embodiment.

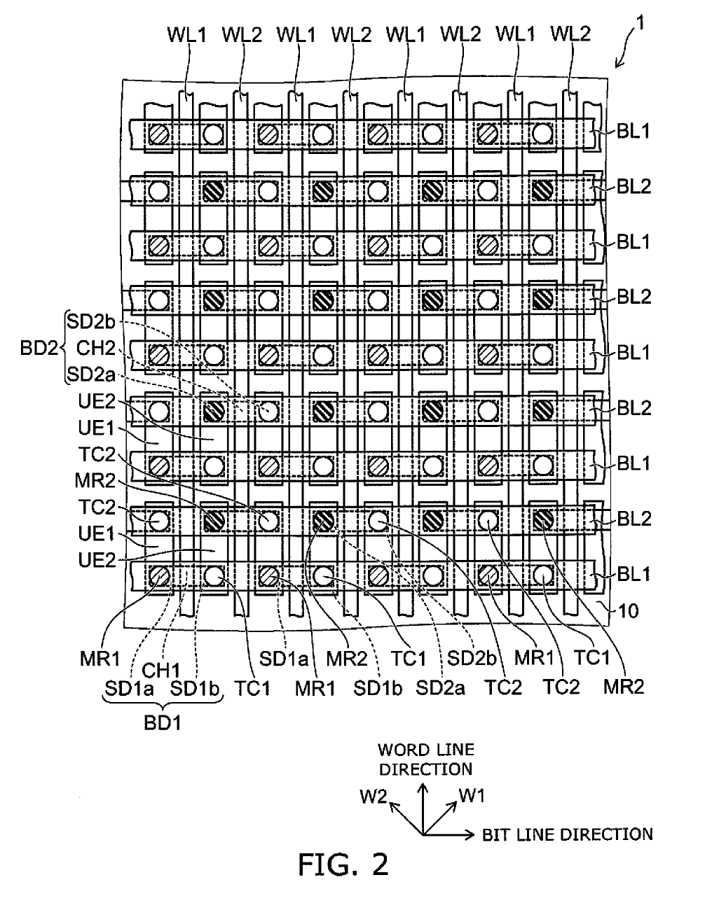

FIG. 2 is a plan view illustrating a magnetic memory device according to the embodiment.

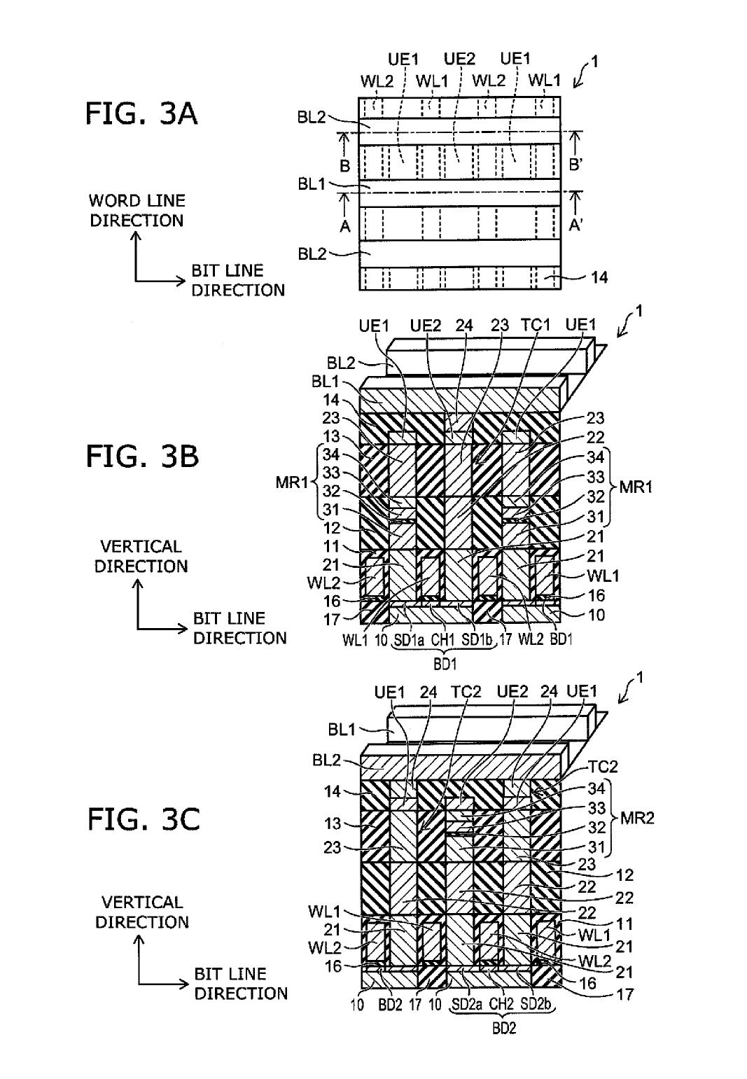

FIG. 3A is a partial plan view illustrating the magnetic memory device according to the embodiment, FIG. 3B is a cross-sectional view taken along A-A′ in FIG. 3A, and FIG. 3C is a cross-sectional view taken along B-B′ in FIG. 3A.

Note that in FIG. 1 and FIG. 2, as a rule, to make the drawings easy to read, only conductive portions are shown. Note also that in FIG. 2, the magneto-resistive effect device would normally be invisible behind the bit line, upper electrode and the like, but here, for the purposes of illustration, the outer portions of the magneto-resistive effect devices are depicted using solid lines and the internal portions are depicted using hashing. The type of hashing differs according to the vertical positioning of the magneto-resistive effect device. Further, in FIG. 3B and FIG. 3C, a top surface of the magnetic memory device is also illustrated.

As illustrated in FIGS. 1, 2 and 3A to 3C, a magnetic memory device 1 according to the embodiment is provided with a silicon substrate 10. On the silicon substrate 10, inter-layer insulating films 11, 12, 13 and 14 are stacked in the stated order, starting from a lower layer side. Hereinafter, a stacking direction of the inter-layer insulating films 11 to 14, which is to say a direction perpendicular to the top surface of the silicon substrate 10, is referred to as a ‘vertical direction’. In the inter-layer insulating film 11, a gate insulating film 16 is provided so as to contact the silicon substrate 10, and the plurality of word lines WL1 and word lines WL2 (hereinafter referred to collectively as ‘word lines WL’) are provided on the gate insulating film 16. The word lines WL1 and word lines WL2 extend in a direction (hereinafter referred to as a ‘word line direction’) and are arranged alternately and periodically at the same height.

On the inter-layer insulating film 14, a plurality of bit lines BL1 and bit lines BL2 (hereinafter referred to collectively as ‘bit lines BL’) are provided. The bit lines BL1 and bit lines BL2 extend in a direction (hereinafter referred to as a ‘bit line direction’) that intersects and may, for example, be perpendicular to the word line direction, and are arranged alternately and periodically at the same height.

In regions that are directly below the bit lines BL1 in the upper layer portion of the silicon substrate 10 and in regions sandwiched by regions directly below the word lines WL1, pairs of source-drain regions SD1a and SD1b are formed. Because the source-drain regions SD1a and SD1b are formed at what is, when the arrangement is viewed from above, each intersection point of the bit lines BL1 and the word lines WL1, a plurality of the pairs of source-drain regions SD1a and SD1b are formed in the silicon substrate 10. A portion between each source-drain region SD1a and source-drain region SD1b in the upper layer portion of the silicon substrate 10 forms a channel region CH1.

A body region BD1 is formed by the pair of source-drain regions SD1a and SD1b and the channel region CH1 between the pair of the source-drain regions SD1a and SD1b. In each body region BD1, the source-drain region SD1a, the channel region CH1 and the source-drain region SD1b are arranged along the bit line direction. Also, the direction going from the source-drain region SD1a to the source-drain region SD1b, is the same in alternate body regions BD1. The body region BD1, the gate insulating film 16 and word line WL1 which are provided directly above the body region BD1 form a Metal-Oxide-Semiconductor Field-Effect Transistor (MOSFET). The word line WL1 functions as a gate electrode for the MOSFET.

Similarly, in regions that are directly below the bit lines BL2 in the upper layer portion of the substrate 10 and in regions sandwiched by regions directly below the word lines WL2, pairs of source-drain regions SD2a and SD2b are formed. Because the source-drain regions SD2a and SD2b are formed at what is, when the arrangement is viewed from above, each intersection point of the bit lines BL2 and the word lines WL2, a plurality of the pairs of source-drain regions SD2a and SD2b are formed in the silicon substrate 10. A portion between each source-drain region SD2a and source-drain region SD2b in the upper layer portion of the silicon substrate 10 forms a channel region CH2.

A body region BD2 is formed by the pair of source-drain regions SD2a and SD2b and the channel region CH2 between the pair of source-drain regions SD2a and SD2b. In each body region BD2, the source-drain region SD2a, the channel region CH2 and the source-drain region SD2b are arranged along the bit line direction. Also, the direction going from the source-drain region SD2a toward the source-drain region SD2b, is the same between BD2 regions, and matches the direction going from the source-drain region SD1a toward the source-drain region SD1b in the body region BD1. A MOSFET is formed by the body region BD2, the gate insulating film 16 and word line WL2 provided directly above the body region BD2. The word line WL2 is a gate electrode for the MOSFET.

Further, a device separating insulating layer (Shallow Trench Isolation (STI)) 17 is selectively provided in the upper layer portion of the silicon substrate 10 to isolate the body regions BD1 and BD2 from each other.

Contacts 21 are respectively provided in regions directly above all the source-drain regions in the inter-layer insulating film 11. The contacts 21 have a vertically-extending columnar form and pierce the inter-layer insulating film 11. When viewed from above, the contacts 21 are arranged in matrix form along the word line direction and the bit line direction. An arrangement period of the contacts 21 in the word line direction is equal to an arrangement period of the word lines WL, and the contacts 21 arranged between the word lines WL1 and the word lines WL2. An arrangement period of the contacts 21 in the bit line direction is equal to an arrangement period of the bit lines BL, and the contacts 21 are provided in regions directly under the bit lines BL1 and the bit lines BL2.

In the inter-layer insulating film 12, a magneto-resistive effect device MR1 and a lower plug 22 are provided. The magneto-resistive effect device MR1 and the lower plug 22 have a vertically-extending columnar form and pierce the inter-layer insulating film 12. The magneto-resistive effect device MR1 is provided in a region directly above the source-drain region SD1a, and a bottom end of the magneto-resistive effect device MR1 is connected to the source-drain region SD1a via the contact 21. The contact 21 connected to the bottom end of the magneto-resistive effect device MR1 functions as a lower electrode of the magneto-resistive effect device MR1. The lower plugs 22, on the other hand, are provided in regions directly above the source-drain regions SD1b, SD2a and SD2b and are connected respectively to the source-drain regions SD1b, SD2a and SD2b via the contacts 21. Thus, in the regions that are directly above the contacts 21 in the inter-layer insulating film 12, the magneto-resistive effect device MR1 and the lower plug 22 are provided. Further, in regions directly below the bit lines BL1, the magneto-resistive effect devices MR1 and the lower plugs 22 are alternately provided. In regions directly below the bit lines BL2, the lower plugs 22 only are provided.

In the inter-layer insulating film 13, a magneto-resistive effect device MR2 and an upper plug 23 is provided. The magneto-resistive effect device MR2 and the upper plug 23 have a vertically-extending columnar form and pierce the inter-layer insulating film 13. The magneto-resistive effect device MR2 is provided in a region directly above the source-drain region SD2a and a bottom end of the magneto-resistive effect device MR2 is connected to the source-drain region SD2a via the lower plug 22 and the contact 21. The lower plug 22 connected to the bottom end of the magneto-resistive effect device MR2 functions as a lower electrode of the magneto-resistive effect device MR2. The upper plugs 23, on the other hand, are provided in regions directly above the source-drain regions SD1a, SD1b and SD2b. The upper plug 23 provided directly above the source-drain region SD1a is connected to the source-drain region SD1a via the magneto-resistive effect device MR1 and the contact 21. The upper plugs 23 provided directly above the source-drain regions SD1b and SD2b are respectively connected to the source-drain regions SD1b and SD2b via the lower plugs 22 and the contacts 21. Thus, in the regions directly above the contacts 21 in the inter-layer insulating film 13, the magneto-resistive effect device MR2 and the upper plug 23 are provided. In the regions directly below the bit lines BL1, only the upper plugs 23 are provided, and in the regions directly below the bit line BL2, the magneto-resistive effect device MR2 and the upper plug 23 are alternately provided.

A through contact TC1 is formed by the contact 21, the lower plug 22, and the upper plug 23 that are provided in the region directly above the source-drain region SD1b. A through contact TC2 is formed by the contact 21, the lower plug 22, and the upper plug 23 that are provided in the region directly above the source-drain region SD2b. The through contacts TC1 and TC2 do not include either of the magneto-resistive effect devices MR1 and MR2.

In a lower portion of the inter-layer insulating film 14, upper electrodes UE1 and UE2 are provided. When viewed from above, the upper electrodes UE1 and UE2 have a rectangular form extending in the word line direction. The upper electrode UE1 is provided to link a region directly above the source-drain region SD1a to a region directly above the source-drain region SD2b, thereby connecting a top end of the magneto-resistive effect device MR1 to a top end of the through contact TC2. The upper electrode UE2 is provided to link a region directly above the source-drain region SD2a to a region directly above the source-drain region SD1b, thereby connecting a top end of the magneto-resistive effect device MR2 to a top end of the through contact TC1.

In an upper portion of the inter-layer insulating film 14, uppermost level plugs 24 are provided. The uppermost level plugs 24 are provided in regions directly above the source-drain regions SD1b and SD2b, which is to say in regions directly above the through contacts TC1 and TC2. A bottom end of the uppermost level plug 24 provided in the region directly above the source-drain region SD1b is connected to the upper electrode UE2, and a top end is connected to the bit line BL1. A bottom end of the uppermost level plug 24 provided in the region directly above the source-drain region SD2b is connected to the upper electrode UE1, and a top end is connected to the bit line BL2.

Thus a current path is formed by the bit line BL2, the uppermost level plug 24, the upper electrode UE1, the upper plug 23, the magneto-resistive effect device MR1, the contact 21, the source-drain region SD1a, the channel region CH1, the source-drain region SD1b, the through contact TC1, the upper electrode UE2, the uppermost level plug 24 and the bit line BL1 in the stated order.

Similarly, a current path is formed by the bit line BL1, the uppermost level plug 24, the upper electrode UE2, the magneto-resistive effect device MR2, the lower plug 22, the contact 21, the source-drain region SD2a, the channel region CH2, the source-drain region SD2b, the through contact TC2, the upper electrode UE1, the uppermost level plug 24 and the bit line BL2 in the stated order.

In this way, a plurality of current paths is connected to each other in parallel between the bit line BL1 and the bit line BL2. Also, in each current path, a single magneto-resistive effect device 1 and a single MOSFET are connected in series.

If no distinction is made between the magneto-resistive effect devices MR1 and MR2 and it is assumed that a single type of magneto-resistive effect device MR is used, the magneto-resistive effect devices MR are arranged in matrix form when viewed from above. If, of the arrangement directions for the magneto-resistive effect devices MR, a direction with the shortest arrangement period is denoted ‘direction W1’ and a direction with the second shortest arrangement period is denoted ‘direction W2’, the magneto-resistive effect devices MR1 and the magneto-resistive effect devices MR2 are alternately arranged in both the direction W1 and the direction W2. Note that both the direction W1 and the direction W2 are inclined with respect to both the word line direction and the bit line direction. Also, when the word line direction and the bit line direction are perpendicular to each other, the arrangement period of the magneto-resistive effect devices MR in the direction W1 and the arrangement period of the magneto-resistive effect devices MR in the direction W2 are equal to each other.

Note also that the magneto-resistive effect devices MR1 are provided in the inter-layer insulating film 12 and the magneto-resistive effect devices MR2 are provided in the inter-layer insulating film 13. Hence, the magneto-resistive effect devices MR2 are positioned above the magneto-resistive effect devices MR1. Thus, a distance between the magneto-resistive effect device MR2 and the silicon substrate 10 is longer than a distance between the magneto-resistive effect device MR1 and the silicon substrate 10.

Of the magneto-resistive effect devices MR, the two magneto-resistive effect devices nearest to each other when viewed from above are the magneto-resistive effect device MR1 and magneto-resistive effect device MR2 that are adjacent to each other in the direction W1 or the direction W2. These magneto-resistive effect devices MR1 and MR2 differ from each other in vertical position, and therefore differ in distance from the silicon substrate 10.

The magneto-resistive effect devices MR1 and MR2 are spin-injection type devices in which the magnetization direction of the memory layer is controlled by injecting electrons for which the spin directions are aligned in a fixed direction. Each of the magneto-resistive effect devices MR1 and MR2 has, for example, a reference layer 31, an insulating layer 32, a memory layer 33 and a cap layer 34, which are stacked starting from the bottom in the stated order. The reference layer 31 is formed from a magnetic material, and has a magnetization direction that is fixed in a direction that is toward the silicon substrate 10 (downward direction) or away from the silicon substrate 10 (upward direction). The memory layer 33 is also formed from a magnetic material and has a magnetization direction that is rotatable between the upward direction and downward direction. The insulating layer 32 is provided between the reference layer 31 and the memory layer 33 and forms a layer that allows a tunnel current to flow while magnetically isolating the reference layer 31 and the memory layer 33. The cap layer 34 is formed from a conducting material. Thus, the magnetization direction of the reference layer 31 and the magnetization direction of the memory layer 33 are perpendicular to a top surface of the silicon substrate 10. In other words, the magneto-resistive effect devices MR1 and MR2 are memory devices of the perpendicular magnetization type.

Next, a method for manufacturing the magnetic memory device according to the embodiment will be explained.

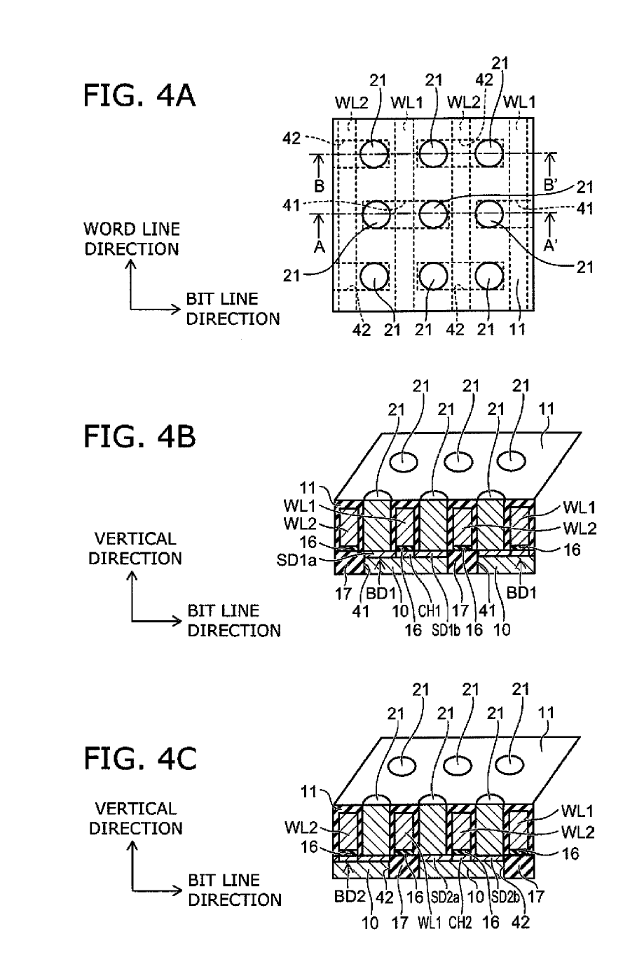

FIGS. 4 to 9 are process views illustrating a manufacturing method of the magnetic memory device according to the embodiment. In each drawing, A is a plan view, B is a cross-sectional view taken along a line A-A′ in A, and C is a cross-sectional view taken along a line B-B′ in A.

Note also that, B and C in each drawing also illustrate a top surface of a structural body part-way through manufacture.

First, as illustrated in FIGS. 4A to 4C, the upper layer portion of the silicon substrate 10 is partitioned to form a plurality of rectangular regions 41 and 42 by forming a device separation insulating layer 17 in the upper layer portion of the silicon substrate 10. When viewed from above, the rectangular regions extend in a direction (bit line direction) and are arranged in a plurality of rows, each row extending along the bit line direction. In each row, the above-described rectangular regions 41 or 42 are periodically arranged along the row. Also, in adjacent rows the rectangular regions 41 and 42 are displaced one half-period relative to each other. In other words, on the top surface of the silicon substrate 10, rows of the rectangular regions 41 alternate with rows of the rectangular regions 42, and the arrangement period of the rectangular regions 41 and the arrangement period of the rectangular regions 42 are displaced relative to each other by one half-period in the bit line direction.

Next, impurities are implanted in the upper layer portion of the silicon substrate 10 to form, for example, p-type wells (not illustrated). Next, a gate insulating film 16 is formed on a top surface of the rectangular regions 41 and 42 on the silicon substrate 10. Next, the word lines WL1 and WL2 are formed on the silicon substrate 10 so as to extend in a direction (the word line direction) that intersects the bit line direction and may, for example, be perpendicular to the bit line direction. The word lines WL1 and the word lines WL2 are alternately arranged with the word lines WL1 passing regions directly above longitudinally central portions of the rectangular regions 41 and the word lines WL2 passing regions directly above longitudinally central portions of the rectangular regions 42.

Next, with the word lines WL1 and WL2 as a mask, impurities are implanted into the silicon substrate 10 to form, for example, n-type source-drain regions in the rectangular area sandwiched by the regions directly below the word lines WL. Here, the regions sandwiched between the source-drain regions in each rectangular region, which is to say the regions directly below the word lines WL, are channel regions.

Hereinafter, the source-drain regions formed on one side of the rectangular regions 41 will be referred to as ‘source-drain region SD1a’ and the source-drain regions on the other side of the rectangular regions 41 will be referred to as ‘source-drain region SD1b’. Further, the source-drain regions formed on one side of the rectangular regions 42 will be referred to as ‘source-drain region SD2a’ and the source-drain regions on the other side of the rectangular regions 42 will be referred to as ‘source-drain region SD2b’. The channel regions formed in the rectangular regions 41 will be referred to as channel region CH1 and channel regions formed in the rectangular regions 42 will be referred to as channel region CH2. The source-drain regions SD1a and SD1b and the channel region CH1 are collectively called the body region BD1, and the source-drain regions SD2a and SD2b and the channel region CH2 are collectively called the body region BD2. The body region BD1, the gate insulating film 16 and the word line WL1 construct an n-channel MOSFET. Moreover, the body region BD2, the gate insulating film 16, and the word line WL2 also construct an n-channel MOSFET.

Next, the inter-layer insulating film 11 is formed on the silicon substrate 10 so as to cover the gate insulating film 16 and the word lines WL1 and WL2. Next, contact holes are formed in regions directly above the source-drain regions in the inter-layer insulating film 11. Next, the contacts 21 are formed by embedding a conducting material in the contact holes. The bottom end of each contact 21 is connected to one of the source-drain regions, and the top end of each contact 21 is exposed at the top surface of the inter-layer insulating film 11.

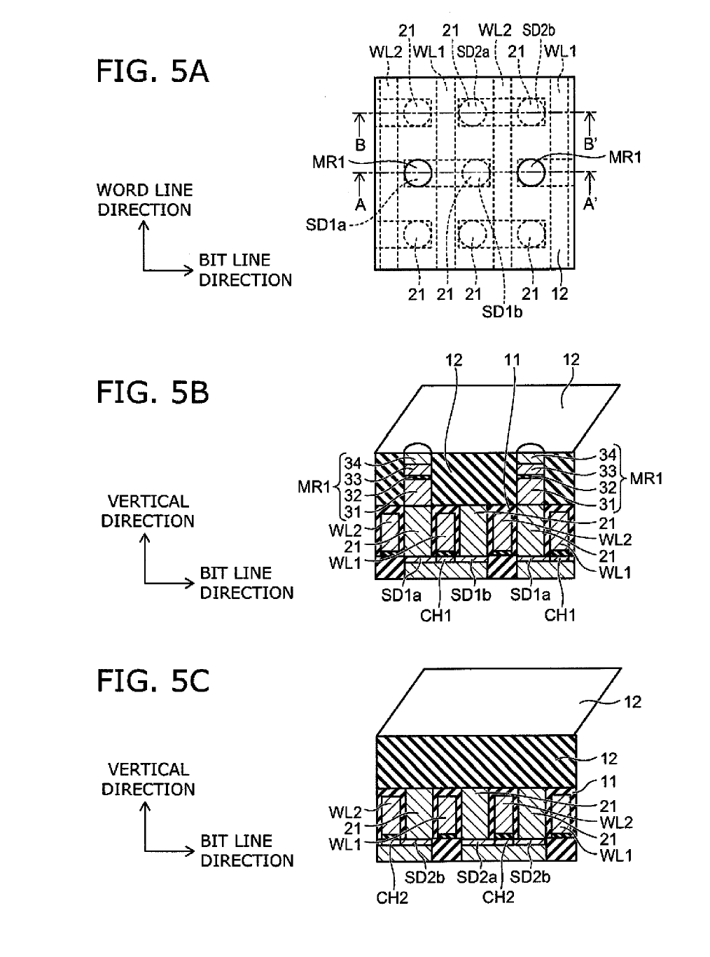

Next, as illustrated in FIGS. 5A to 5C, the reference layer 31 formed from a magnetic material, the insulating layer 32, the memory layer 33 formed from a magnetic material, and the cap layer 34 are formed in the stated order on the inter-layer insulating film 11. Next, the cap layer 34 is processed so as to be left on a region directly above the source-drain region SD1a and be removed from all other regions. Next, etching is performed with the processed cap layer 34 as a mask, and the memory layer 33, the insulating layer 32 and the reference layer 31 are selectively removed. As a result, the magneto-resistive effect device MR1 is formed with the reference layer 31, the insulating layer 32, the memory layer 33 and the cap layer 34 stacked in the stated order on the contact 21 provided in the region directly above the source-drain region SD1a. Here, the bottom end of the magneto-resistive effect device MR1 is connected to the top end of the contact 21. Next, the inter-layer insulating film 12 is formed on the inter-layer insulating film 11 so as to cover the magneto-resistive effect device MR1 and the top surface is flattened to expose the cap layer 34.

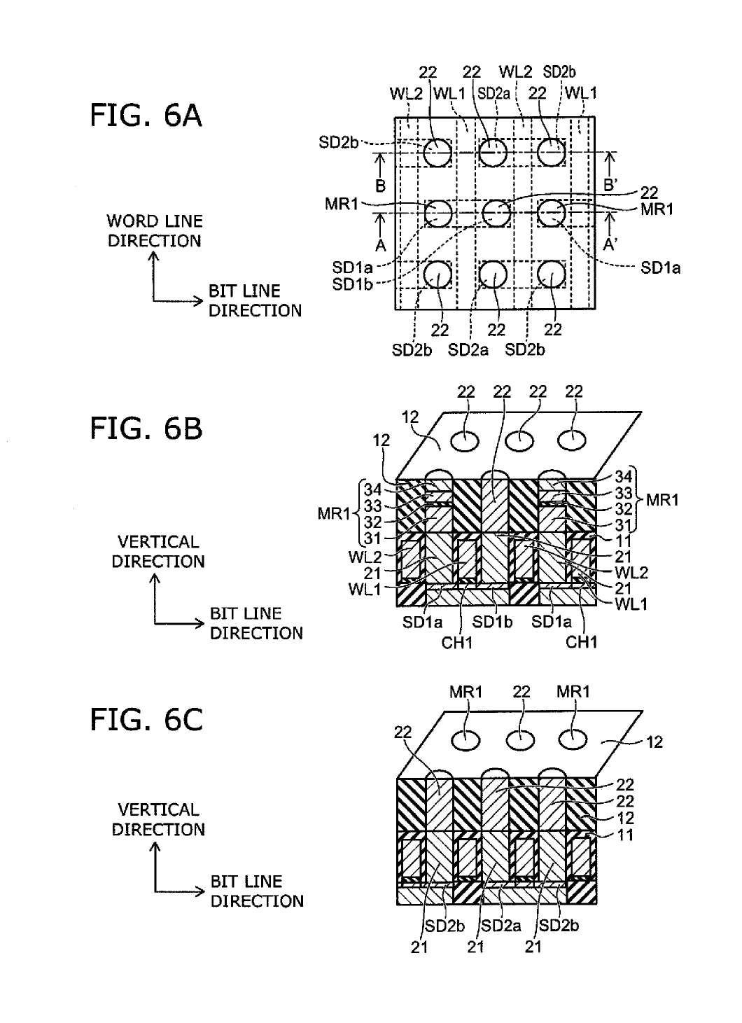

Next, as illustrated in FIGS. 6A to 6C, via holes are formed in the regions directly above the source-drain regions SD1b, SD2a and SD2b in the inter-layer insulating film 12. Next, conducting material is embedded in the via holes to form the lower plugs 22. The bottom ends of the lower plugs 22 are connected to the top ends of the contacts 21.

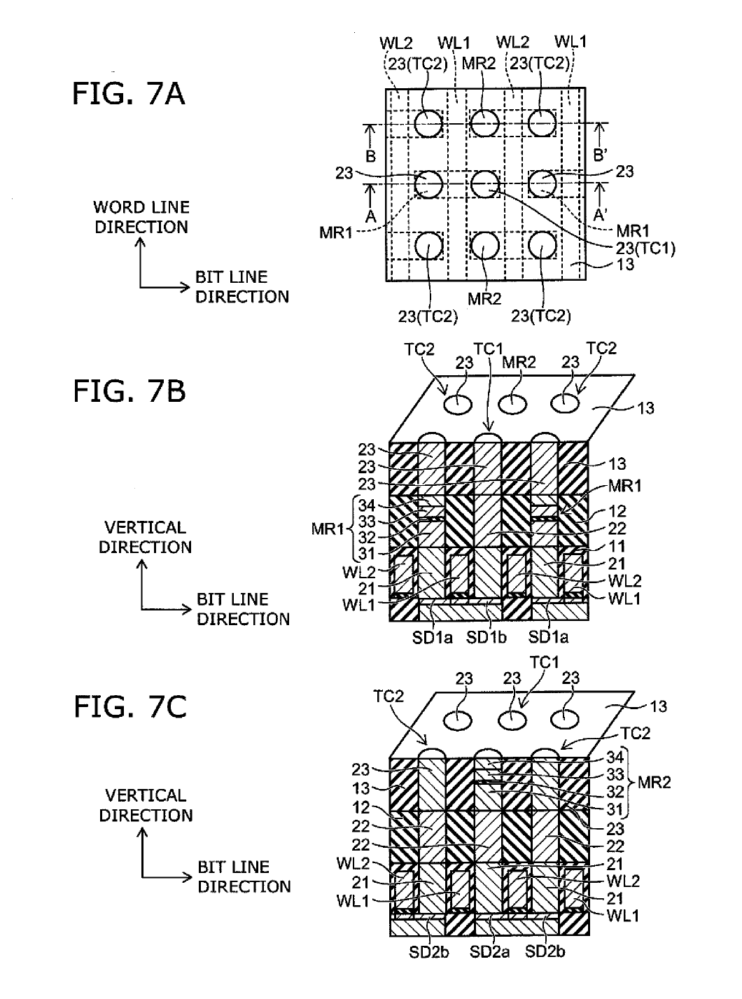

Next, as illustrated in FIGS. 7A to 7C, the reference layer 31 formed from a magnetic material, the insulating layer 32, the memory layer 33 formed from a magnetic material and the cap layer 34 are formed in the stated order on the inter-layer insulating film 12. Then, using a method identical to that described above, the magneto-resistive effect device MR2 is formed in a region directly above the source-drain region SD2a. Next, the inter-layer insulating film 13 is formed on the inter-layer insulating film 12 so as to cover the magneto-resistive effect device MR2 and the top surface is flattened to expose the cap layer 34 of the magneto-resistive effect device MR2.

Next, via holes are formed in the regions directly above the source-drain regions SD1b and SD2b in the inter-layer insulating film 13. Next, a conducting material is embedded in the via holes to form the upper plugs 23. The bottom ends of the upper plugs 23 are connected to the top end of the magneto-resistive effect device MR1 or the top end of the lower plugs 22. Here, the through contact TC1 is formed by the contact 21, the lower plug 22, and the upper plug 23 that are provided in the region directly above the source-drain region SD1b. Further, the through contact TC2 is formed by the contact 21, the lower plug 22, and the upper plug 23 that are provided in the region directly above the source-drain region SD2b.

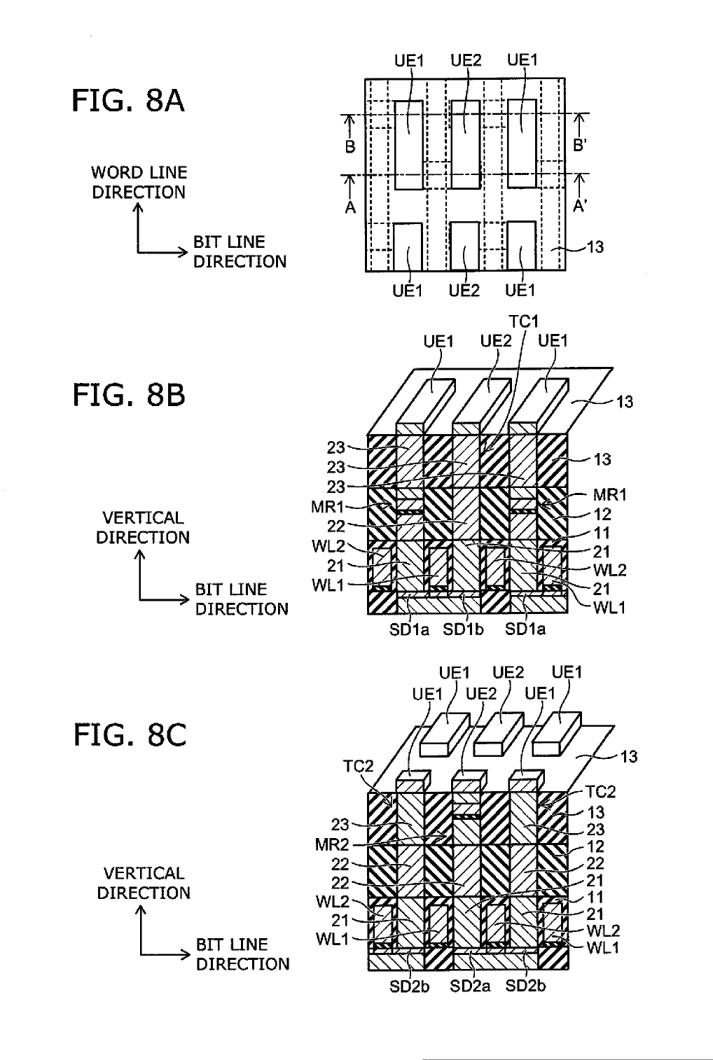

Next, as illustrated in FIGS. 8A to 8C, a conductive film is formed on the inter-layer insulating film 13 and selectively removed to form the upper electrodes UE1 and UE2. The upper electrode UE1 is formed with a rectangular form that extends in the word line direction, and so as to link the region directly above the source-drain region SD1a and the region directly above the source-drain region SD2b, thereby connecting between the magneto-resistive effect device MR1 and the through contact TC2. The upper electrode UE2 is formed with a rectangular form that extends in the word line direction, and so as to link the region directly above the source-drain region SD2a and the region directly above the source-drain region SD1b, thereby connecting between the magneto-resistive effect device MR2 and the through contact TC1. As a result, when viewed from above, the upper electrodes UE1 and UE2 are arranged in matrix form. In the word line direction, rows of only the upper electrodes UE1 and rows of only the upper electrodes UE2 are provided. In the bit line direction, the upper electrodes UE1 and upper electrode UE2 are alternately provided.

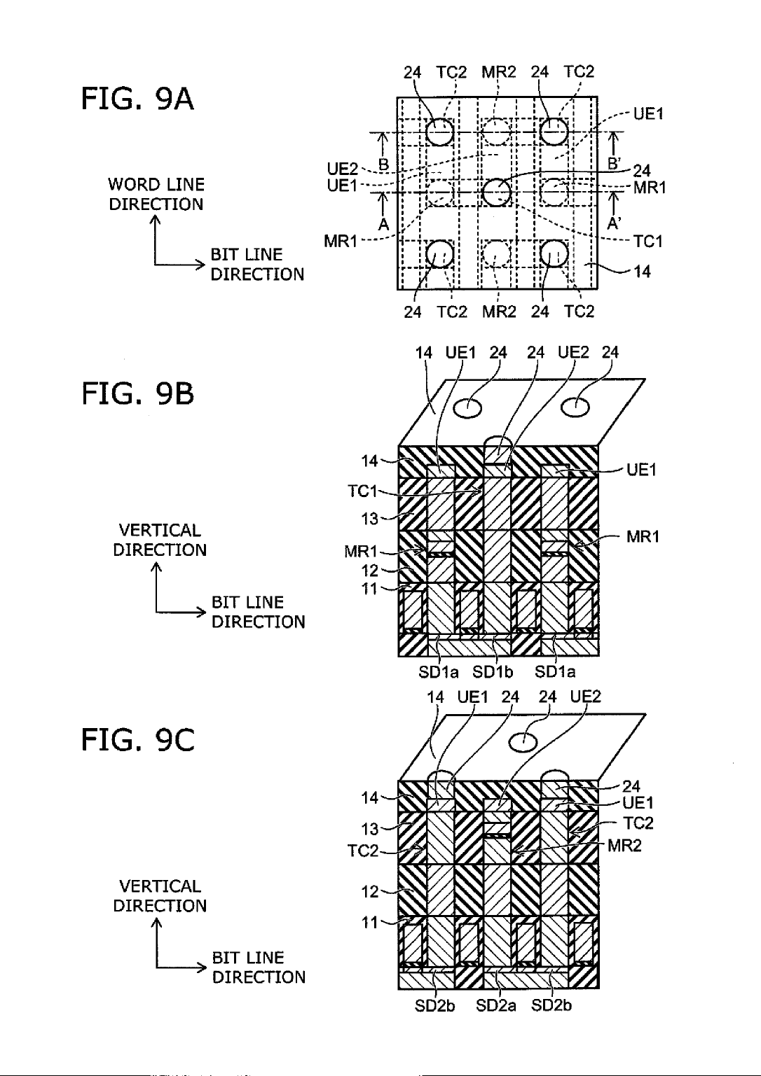

Next, as illustrated in FIGS. 9A to 9C, the inter-layer insulating film 14 is formed on the inter-layer insulating film 13 so as to cover the upper electrodes UE1 and UE2. Next, via holes are formed in regions directly above the source-drain regions SD1b and SD2b in the inter-layer insulating film 14, which is to say in regions directly above the through contacts TC1 and TC2, and a conducting material is embedded in the via holes to form the uppermost level plug 24. Here, the uppermost level plugs 24 are not formed in the regions directly above the magneto-resistive effect devices MR1 and MR2.

Next, as illustrated in FIGS. 3A to 3C, a conductive film is formed on the inter-layer insulating film 14 and selectively removed to form the bit lines BL1 and BL2 extending in the bit line direction. Here, the bit lines BL1 are arranged so as to link to regions directly above the body regions BD1, and the bit lines BL2 are arranged to link to regions directly above the body region BD2. Accordingly, the bit lines BL1 and the bit lines BL2 are arranged to alternate. The bit lines BL1 are connected to the upper electrodes UE2 via the uppermost level plugs 24 and the bit lines BL2 are connected to the upper electrodes UE1 via the uppermost level plug 24. In this way, the magnetic memory device 1 according to the embodiment is manufactured.

Next, the effects of the embodiment will be explained.

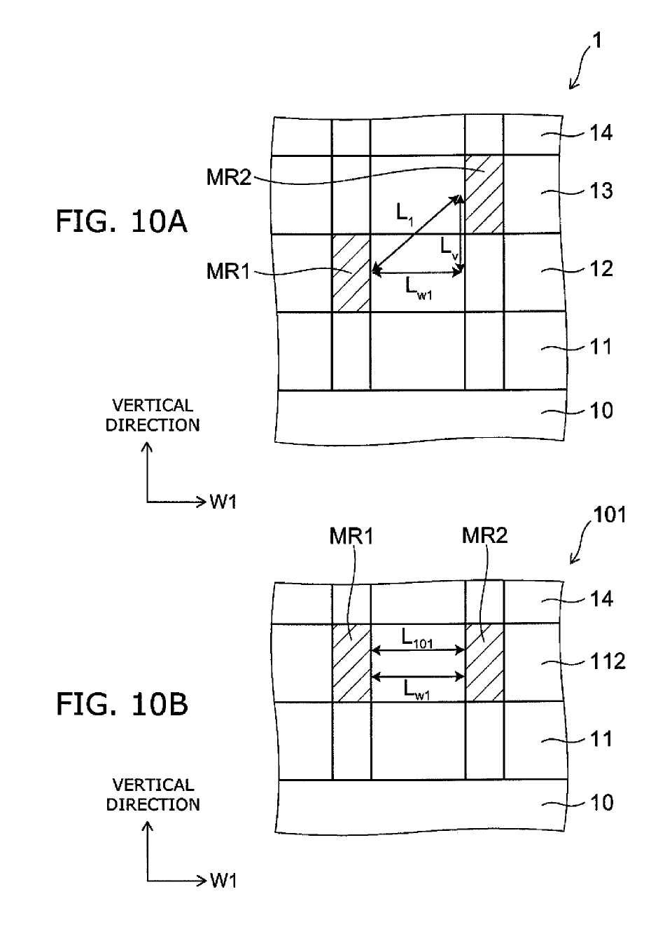

FIGS. 10A and 10B are views illustrating the effects of the embodiment, with 10A illustrating the embodiment and 10B illustrating a comparative example.

As illustrated in FIG. 10A, the magnetic memory device 1 according to the embodiment has the magneto-resistive effect device MR1 provided in the inter-layer insulating film 12 and the magneto-resistive effect device MR2 provided in the inter-layer insulating film 13. Accordingly, when the magneto-resistive effect devices MR are viewed from above, the two magneto-resistive effect devices nearest each other, which is to say any two magneto-resistive effect devices MR1 and MR2 adjacent to each other in the direction W1 that has the shortest arrangement period, differ from each other in vertical position. Hence, since a distance L₁ between the magneto-resistive effect devices MR1 and MR2 is effectively a composition of a direction W1 distance L_{W1} and a vertical distance L_{V}, the distance L₁ is longer than the W1 direction distance L_{W1}. Consequently, the effects of magnetic field leakage from one magneto-resistive effect device MR on the magnetization direction of the memory layer of another magneto-resistive effect device MR is reduced and instability in the operation of the magneto-resistive effect devices caused by interference between the magneto-resistive effect devices can be suppressed, even when the distance between the magneto-resistive effect devices MR is shortened. As a result, the level of integration of magneto-resistive effect devices MR in the magnetic memory device 1 can be improved.

On the other hand, as illustrated in FIG. 10B, in the magnetic memory devices 101 according to the comparative example, all of the magneto-resistive effect devices MR are formed in the same inter-layer insulating film 112. Accordingly, when the magneto-resistive effect devices MR are viewed from above, the two magneto-resistive effect devices MR1 and MR2 which are nearest each other have the same vertical position. Hence, a distance L₁₀₁ between the two magneto-resistive effect devices MR is equal to the distance L_{W1} in the direction W1, which is shorter than the distance L₁ in the embodiment. Consequently, the effect of the magnetic field leakage of one magneto-resistive effect device MR on the magnetization direction of the memory layer of another magneto-resistive effect device MR is large.

As a result, when the distance between the magneto-resistive effect devices MR is shortened, the operation of the magneto-resistive effect devices becomes unstable. For example, if magnetic field leakage from a given magneto-resistive effect device MR1 acts to push the magnetization direction of an adjacent magneto-resistive effect device MR2 to the downward direction, it may prove difficult to set the magnetization direction of the memory layer of the magneto-resistive effect device MR2 to the upward direction, even after a predetermined amount of spin implantation. Further, even when not attempting to set the magnetization direction of the memory layer of the magneto-resistive effect device MR2, the magnetic field leakage from the magneto-resistive effect device MR1 may set magnetization direction in the downward direction. Thus, erroneous operation becomes more likely in data-writing operations and data-deleting operations. To reliably prevent erroneous operation, it is necessary to increase the distance between magneto-resistive effect devices or widen the operating margins, both of which prevent increasing the level of integration of the magnetic memory device.

Further, according to the embodiment, the magneto-resistive effect devices and the through contacts are arranged alternately in both the word line direction and the bit line direction, and so the direction W1 with the shortest arrangement period and the direction W2 with the second shortest arrangement period of the arrangement directions of the magneto-resistive effect devices can be set at an incline with respect to both the word line direction and the bit line direction. As a result, the arrangement period of the magneto-resistive effect devices can be set to be longer than the arrangement period in the word line WL and the arrangement period of the bit lines BL. Hence, interference between the magneto-resistive effect devices is further suppressed and higher levels of integration can be facilitated.

The above described effects are of particular benefit in spin-injection type magnetic memory devices. In spin-injection type magnetic memory devices, space far forming magnetic fields around the word line and the bit line are not required, and so the arrangement periods of the word line and bit line can be shortened. However, as the arrangement periods of the word lines and bit lines are shortened, the arrangement period are also shortened, increasing the interference between the magneto-resistive effect devices. Thus, the interference between the magneto-resistive effect devices prevents higher level integration of the magnetic memory device.

By contrast, with the embodiment, the interference between the magneto-resistive effect devices is suppressed in the manner described above. Hence, the obstructive effects of interference can be avoided and significantly higher level of integration in the magnetic memory device can be facilitated.

Note also that although in the embodiment an example was described in which the lower magnetic material of the magneto-resistive effect device was the reference layer and the upper magnetic material was the memory layer, the stacking direction may be reversed. In other words, the same effects as with the embodiment can be achieved when an upper magnetic material is used as the reference layer and the lower magnetic material as the memory layer. Also, in the magneto-resistive effect device, an adjustment layer may be provided to shift the magnetic fields to cancel out the magnetic field leakage. Further, although in the embodiment an example was described in which the uppermost level plugs 24 were provided directly above the through contacts TC1 and TC2, the invention is not limited to the arrangement. Provided that the uppermost level plugs 24 are connected between the upper electrode and the bit lines, the uppermost level plugs may, for example, be provided in regions directly above the magneto-resistive effect devices MR1 and MR2. Furthermore, the bit lines BL1 and BL2 need not be provided in regions directly above the body regions BD1 and BD2.

According the embodiment described above, it is possible to realize a magnetic memory device with a high level of integration.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A magnetic memory device comprising:
a semiconductor substrate;
a gate insulating film provided on the semiconductor substrate;
a plurality of first and second word lines provided on the gate insulating film, extending in a first direction, and arranged alternately;
a first bit line and a second bit line provided on the first and second word lines and extending in a second direction that is perpendicular to the first direction;
a plurality of pairs of first source-drain regions formed at intersections of the first word lines and the first bit line, each pair of the first source-drain regions being formed in regions sandwiching a region directly below each of the first word lines in the semiconductor substrate when viewed from above,
a plurality of pairs of second source-drain regions formed at intersections of the second word lines and the second bit line, each pair of the second source-drain regions being formed in regions sandwiching a region directly below each of the second word lines in the semiconductor substrate when viewed from above,
spin-injection type first magneto-resistive effect devices, a bottom end of each of the first magneto-resistive effect devices being connected to one region of each of the pairs of first source-drain regions;
spin-injection type second magneto-resistive effect devices, a bottom end of each of the second magneto-resistive effect devices being connected to one region of each of the pairs of second source-drain regions;
first contacts, a bottom end of each of the first contacts being connected to another region of each of the pairs of first source-drain regions;
second contacts, a bottom end of each of the second contacts being connected to another region of each of the pairs of second source-drain regions;
first upper electrodes connected to top ends of the first magneto-resistive effect devices, top ends of the second contacts, and the second bit line; and
second upper electrodes connected to top ends of the second magneto-resistive effect devices, top ends of the first contacts, and the first bit line,
the second magneto-resistive effect devices being disposed above the first magneto-resistive effect devices.

2. The device according to claim 1, further comprising:
a first inter-layer insulating film provided on the semiconductor substrate, the first magneto-resistive effect devices being disposed in the first inter-layer insulating film;
a second inter-layer insulating film provided on the first inter-layer insulating film, the second magneto-resistive effect devices being disposed in the second inter-layer insulating film;
lower plugs provided in the first inter-layer insulating film, each of the lower plugs being connected between the one region of each of the pairs of second source-drain regions and the bottom end of each of the second magneto-resistive effect devices; and
upper plugs provided in the second inter-layer insulating film, each of the upper plugs being connected between the top end of each of the first magneto-resistive effect devices and each of the first upper electrodes.

3. The device according to claim 1, wherein a direction from the one region to the another region of each pair of the first source-drain regions is the same direction as a direction from the one region to the another region of each pair of the second source-drain regions.

4. The device according to claim 3, wherein the first and second upper electrodes extend in the first direction.

5. The device according to claim 1, wherein
the first and second magneto-resistive effect devices are arranged in matrix form when viewed from above, and
the first and second magneto-resistive effect devices are arranged alternately both along a first arrange direction having a shortest arrangement period and along a second arrange direction having a second shortest arrangement period among arrangement directions of the first and second magneto-resistive effect devices.

6. The device according to claim 1, wherein
the first and second magneto-resistive effect devices each include:
a reference layer formed from a magnetic material and having a magnetization direction fixed in a direction toward the semiconductor substrate or in a direction away from the semiconductor substrate;
a memory layer formed from a magnetic material and having a magnetization direction that is rotatable; and
an insulating layer provided between the reference layer and the memory layer.

7. The device according to claim 1, wherein the first direction and the second direction are mutually perpendicular.

8. A magnetic memory device comprising:
a substrate; and
a plurality of magneto-resistive effect devices provided on the substrate,
two of the plurality of magneto-resistive effect devices, that are nearest to each other when viewed from above, differing from each other in distance from the substrate.

9. The device according to claim 8, further comprising:
a first inter-layer insulating film provided on the substrate; and
a second inter-layer insulating film provided on the first interlayer insulating film,
the plurality of magneto-resistive effect devices being arranged in matrix form when viewed from above,
the plurality of magneto-resistive effect devices being arranged to alternate between being in the first inter-layer insulating film and being in the second inter-layer insulating film, both along a first arrange direction having a shortest arrangement period and along a second arrange direction having a second shortest arrangement period among arrangement directions of the magneto-resistive effect devices.

10. The device according to claim 8, wherein
each of the magneto-resistive effect devices includes:
a reference layer formed from a magnetic material and having a magnetization direction fixed in a direction toward the substrate or in a direction away from the substrate;
a memory layer formed from a magnetic material and having a magnetization direction that is rotatable; and
an insulating layer provided between the reference layer and the memory layer.

11. The device according to claim 8, wherein the magneto-resistive effect devices are spin-injection type devices.
